(19) United States
(12) Patent Application Publication
(10) Pub. No.: US 2011/0005594 A1
(43) Pub. Date: Jan. 13, 2011

(54) Photovoltaic Devices Including Zinc

(75) Inventors: Rick C. Powell, Ann Arbor, MI (US); Markus Gloeckler, Perrysburg, OH (US); Benyamin Buller, Sylvania, OH (US); Rui Shao, Sylvania, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/833,960

(22) Filed: Jul. 10, 2010

Related U.S. Application Data
(60) Provisional application No. 61/224,658, filed on Jul. 10, 2009.
(60) Provisional application No. 61/225,013, filed on Jul. 13, 2009.

(51) Int. Cl. H01L 31/0272

(52) U.S. Cl. 136/258; 438/94; 136/260

(57) ABSTRACT

A method of manufacturing a photovoltaic cell may include depositing a cadmium sulfide layer on a transparent conductive oxide stack; depositing a zinc-containing layer on the cadmium sulfide layer; and depositing a cadmium telluride layer on the zinc-containing layer.

### CLAIM FOR PRIORITY

This application claims priority under 35 U.S.C. §119(e) to U.S. Provisional Patent Application Ser. No. 61/224,658 filed on Jul. 10, 2009, and U.S. Provisional Patent Application Ser. No. 61/225,013 filed on Jul. 13, 2009, which are hereby incorporated by reference.

### TECHNICAL FIELD

This invention relates to photovoltaic devices and semiconductor layers with zinc.

### BACKGROUND

During the fabrication of photovoltaic devices, layers of semiconductor material can be applied to a substrate with one layer serving as a window layer and a second layer serving as the absorber layer. The window layer can allow the penetration of solar radiation to the absorber layer, where the optical power is converted into electrical power. Some photovoltaic devices can use transparent thin films that are also conductors of electrical charge.

The conductive thin films can include transparent conductive layers that contain a transparent conductive oxide such as cadmium stannate oxide. The transparent conductive layer can allow light to pass through a semiconductor window layer to the active light absorbing material and also serve as an ohmic contact to transport photogenerated charge carriers away from the light absorbing material. A back electrode can be formed on the back surface of a semiconductor layer.

### DESCRIPTION OF DRAWINGS

FIG. 1 is a schematic of a photovoltaic device having multiple layers.

FIG. 2 is a schematic of a photovoltaic device having multiple layers.

### DETAILED DESCRIPTION

A photovoltaic cell can include a transparent conductive oxide layer adjacent to a substrate and layers of semiconductor material. The layers of semiconductor material can include a bi-layer, which may include an n-type semiconductor window layer, and a p-type semiconductor absorber layer. The n-type window layer and the p-type absorber layer may be positioned in contact with one another to create an electric field. Photons can free electron-hole pairs upon making contact with the n-type window layer, sending electrons to the n side and holes to the p side. Electrons can flow back to the p side via an external current path. The resulting electron flow provides current, which combined with the resulting voltage from the electric field, creates power. The result is the conversion of photon energy into electric power.

A photovoltaic cell can thus include a cadmium sulfide window layer and a cadmium telluride absorber layer. A cadmium zinc sulfide layer can be incorporated to widen the band-gap energy and allow for the tuning of the band-offset between the cadmium zinc sulfide and the cadmium telluride. The cadmium zinc sulfide layer may be produced through a variety of techniques, including the deposition of a zinc-containing layer. For example, a cadmium zinc telluride layer can be deposited onto a cadmium sulfide layer, thereby allowing the zinc to diffuse into the cadmium sulfide, either via a post-deposition annealing step, or by depositing the layers at a high temperature, as in vapor transport deposition, for example. Similarly, a zinc sulfide layer can be deposited onto a cadmium sulfide layer, allowing the zinc to diffuse. Alternatively, cadmium, zinc, and sulfur powder can be mixed together and subsequently deposited. Devices manufactured consistent with this structure have demonstrated increased open circuit voltage and short circuit current. However, it would be desirable to control the exchange reaction between the cadmium sulfide layer and the cadmium zinc telluride layer by variation of the zinc content alone.

Control over the reaction of cadmium sulfide into cadmium zinc sulfide can be obtained by varying the initial zinc distribution of the structure. For example, the reaction can be stimulated by depositing a pure zinc telluride layer and then sustained by the deposition of a layer with a lower zinc percentage cadmium zinc telluride layer. The conversion of the cadmium sulfide into cadmium zinc sulfide can occur during deposition, without requiring anneal. The combination of the two layers can allow better controllability of the overall conversion. Suitable structures include CdS/ZnTe/CdZnTe/CdTe, CdS/CdZnTe/CdTe, CdS/ZnTe/CdTe, CdS/ZnS/CdTe, and derivatives or variations thereof. The layer thicknesses of the zinc telluride layer can be such that sufficient zinc is provided to convert the cadmium sulfide layer to the desired degree if there is no other zinc-containing layer present, or less than desired, for example, 20% to about 40% zinc in cadmium zinc sulfide, but then continued due to the deposition of a cadmium zinc telluride film with a zinc content of 5% to about 10%. The degree of crystallinity can vary, for example, the cadmium zinc sulfide can be nearly amorphous, or highly crystalline.

In one aspect, a method of manufacturing a photovoltaic cell may include depositing a cadmium sulfide layer on a transparent conductive oxide stack; depositing a zinc-containing layer on the cadmium sulfide layer; and depositing a cadmium telluride layer on the zinc-containing layer.

The method may include forming a cadmium zinc sulfide, where the forming includes annealing one or more layers. One or more of the depositing steps may occur at a temperature in a range of about 400 C. to about 800 C., about 500 C. to about 700 C., or about 550 C. to about 650 C. One or more of the depositing steps may occur at about 550 C. or about 600 C. One or more of the depositing steps may include transporting a vapor. The method may include annealing the cadmium sulfide layer and the zinc-containing layer. The method may include annealing the cadmium telluride layer. The annealing may include heating the cadmium sulfide layer and the zinc-containing layer at a temperature in a range of about 400 C. to about 800 C., about 500 C. to about 700 C., or about 550 C. to about 650 C. The annealing may include heating the cadmium sulfide layer and the zinc-containing layer at about 550 C. or about 650 C. The zinc-containing layer may include zinc telluride or cadmium zinc telluride. The cadmium zinc telluride may have a zinc content of about 2% to about 10%. The cadmium zinc telluride may have a zinc content in a range of about 4% to about 8%. The cadmium zinc telluride may have a zinc content in a range of about 5% to about 6%. One or more of the depositing steps may control the exchange reaction between the cadmium sulfide layer and the cadmium zinc telluride. The zinc-containing layer may also include zinc sulfide. The zinc-containing layer may include a cadmium zinc telluride layer on a zinc telluride layer. The cadmium zinc telluride layer may include a zinc concentration that is less than that of the zinc telluride layer. The cadmium zinc telluride layer may have a zinc content of about 2% to about 10%. The cadmium zinc telluride layer may have a zinc content in a range of about 4% to about 8%. The cadmium zinc telluride layer may have a zinc content in a range of about 5% to about 6%. One or more of the depositing steps may control the exchange reaction between the cadmium sulfide layer and the cadmium zinc telluride layer. The transparent conductive oxide stack may include a buffer layer on a transparent conductive oxide layer, where the transparent conductive oxide layer is positioned on one or more barrier layers.

The method may include depositing the transparent conductive oxide stack on a first substrate. The first substrate may include a glass, for example, a soda-lime glass. Each of the one or more barrier layers may include a silicon nitride, aluminum-doped silicon nitride, silicon oxide, aluminum-doped silicon oxide, boron-doped silicon nitride, phosphorous-doped silicon nitride, silicon oxide-nitride, or tin oxide. The transparent conductive oxide layer may include a layer of cadmium and tin, tin oxide, or zinc oxide. The buffer layer may include a zinc tin oxide, tin oxide, zinc oxide, or zinc magnesium oxide. The method may include annealing the transparent conductive oxide stack. The method may include depositing a back contact on the cadmium telluride layer. The method may include depositing a back support on the back contact.

In one aspect, a photovoltaic cell may include a cadmium zinc sulfide layer and a cadmium telluride layer on the cadmium zinc sulfide layer, where the cadmium zinc sulfide layer has an increased efficiency.

The crystallinity of the cadmium zinc sulfide layer may be high or nearly amorphous. The cadmium zinc sulfide layer may have about 20% to about 40% zinc. The photovoltaic cell may include a cadmium zinc telluride layer between the cadmium zinc sulfide layer and the cadmium telluride layer. The cadmium zinc telluride layer may have a zinc content of about 2% to about 10%. The cadmium zinc telluride layer may have a zinc content in a range of about 4% to about 8%. The cadmium zinc telluride layer may have a zinc content in a range of about 5% to about 6%. The photovoltaic cell may include a transparent conductive oxide stack, where the cadmium zinc sulfide layer is positioned on the transparent conductive oxide stack. The photovoltaic cell may include a first substrate, where the transparent conductive oxide stack is positioned on the first substrate. The first substrate may include a glass, for example, a soda-lime glass.

The transparent conductive oxide stack may include a buffer layer on a transparent conductive oxide layer, where the transparent conductive oxide layer is positioned on one or more barrier layers. The transparent conductive oxide layer may include cadmium stannate, tin oxide, or zinc oxide. The buffer layer may include a zinc tin oxide, tin oxide, zinc oxide, or zinc magnesium oxide. Each of the one or more barrier layers may include a silicon nitride, aluminum-doped silicon nitride, silicon oxide, aluminum-doped silicon oxide, boron-doped silicon nitride, phosphorous-doped silicon nitride, silicon oxide-nitride, or tin oxide. The photovoltaic cell may include a back contact on the cadmium telluride layer, and a back support on the back contact.

In one aspect, a photovoltaic cell may also include a cadmium sulfide layer, a zinc-containing layer on the cadmium sulfide layer, and a cadmium telluride layer on the zinc-containing layer.

The zinc-containing layer may include zinc telluride, zinc sulfide, cadmium zinc telluride, or a cadmium zinc telluride layer on a zinc telluride layer. The photovoltaic cell may include a transparent conductive oxide stack on a substrate, where the transparent conductive oxide stack includes a transparent conductive oxide layer on one or more barrier layers, and a buffer layer on the transparent conductive oxide layer, where the cadmium sulfide layer is positioned on the transparent conductive oxide stack.

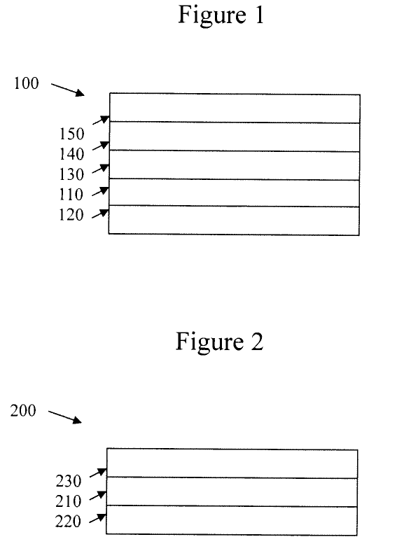

Referring to FIG. 1, a photovoltaic cell 100 can include a cadmium sulfide layer 110. The cadmium sulfide layer 110 can be deposited on a substrate 120. The substrate 120 can include a glass, for example, a soda-lime glass. A zinc-containing layer can be deposited on cadmium sulfide layer 110. For example, a zinc telluride layer 130 can be deposited on the cadmium sulfide layer 110. Other zinc-containing layers may also be deposited on cadmium sulfide layer 110, including cadmium zinc telluride and zinc sulfide. A cadmium zinc telluride layer 140 can be deposited on the zinc telluride layer 130. The layers can be deposited at a high temperature, for example, above about 380 C. to facilitate diffusion of zinc to form cadmium zinc sulfide. For example, the device layers can be deposited at about 400 C. or about 420 C. The layers can be deposited at any suitable temperature range, including, for example, about 400 C. to about 800 C., about 500 C. to about 700 C., or about 550 C. to about 650 C. For example, the layers can be deposited at about 550 C. For cadmium zinc telluride layer 140, any percentage of zinc is viable. For example, about 0.1% zinc should improve performance. A configuration of Cd₁₋ₓZnₓ with x in the range of about 0.10 to about 0.12 has proven particularly beneficial, though anything in the range of about 0 to about 0.30 (i.e., 0 to about 15% zinc) would be acceptable. It should be noted that the optimal percentage of zinc for the cadmium zinc telluride layer can vary depending on deposition details (i.e., temperature profile). A cadmium telluride layer 150 can be deposited on the cadmium zinc telluride layer 140, or directly upon the preceding zinc-containing layer. The multilayer structure can be annealed prior to or after deposition of cadmium telluride layer 150. The annealing can take place under any suitable conditions. For example, the annealing can occur in the presence of a gas selected to control an aspect of the annealing, for example nitrogen gas. The annealing can take place under any suitable pressure, for example, under reduced pressure, in a low vacuum, or at about 0.01 Pa (10⁻⁴ Torr). The annealing can also take place at any suitable temperature or temperature range, for example above about 380 C. The multilayer structure can be annealed at about 400 C. to about 800 C., about 500 C. to about 700 C., or about 550 C. to about 650 C. The structure can also be annealed for any suitable duration, for example, about 10 to about 25 minutes, or about 15 to about 20 minutes.

A variety of deposition techniques are available for depositing the layers discussed above, including for example, low pressure chemical vapor deposition, atmospheric pressure chemical vapor deposition, plasma-enhanced chemical vapor deposition, thermal chemical vapor deposition, DC. or AC. sputtering, spin-on deposition, and spray-pyrolysis. For example, the cadmium sulfide and zinc sulfide layers can be sputtered. The cadmium zinc telluride, cadmium sulfide, cadmium telluride, and zinc telluride can all be deposited using vapor transport deposition.

Diffusion of one or more chemicals from layers in the configurations discussed above can lead to generation of photovoltaic cell 200 from FIG. 2. For example, the zinc from zinc telluride layer 130 can diffuse into cadmium sulfide layer 110, resulting in the formation of cadmium zinc sulfide. The thickness of the deposited zinc telluride from FIG. 1 can be governed by controlling the conversion of cadmium sulfide to cadmium zinc sulfide. Referring to FIG. 2, photovoltaic cell 200 can include a cadmium zinc sulfide layer 210. Cadmium zinc sulfide layer 210 can contain any suitable amount of zinc. Testing has shown that any zinc percentage above zero can be beneficial in increasing transmission and band-alignment. Compositions with a zinc percentage in the 20% to about 40% range (i.e., compositions ranging from Cd_{0.6}Zn_{0.4}S to Cd_{0.2}Zn_{0.8}S) have shown particularly high efficiencies. The cadmium zinc sulfide layer 210 can be located on a substrate 220. The substrate 220 can include a glass, for example, a soda-lime glass. A cadmium telluride layer 230 can be located on the cadmium zinc sulfide layer 110. In one variation, the generated structure can include a cadmium zinc telluride between the cadmium zinc sulfide and the cadmium telluride.

Each layer can be deposited at a different deposition station of a manufacturing line with a separate deposition gas supply and a vacuum-sealed deposition chamber at each station as required. The substrate can be transferred from deposition station to deposition station via a rolling conveyor until all of the desired layers are deposited. A top substrate layer can be placed on top of the top layer to form a sandwich and complete the photovoltaic cell.

Deposition of semiconductor layers in the manufacture of photovoltaic devices is described, for example, in U.S. Pat. Nos. 5,248,349, 5,372,646, 5,470,397, 5,536,333, 5,945,163, 6,037,241, and 6,444,043, each of which is incorporated by reference in its entirety. The deposition can involve transport of vapor from a source to a substrate, or sublimation of a solid in a closed system. An apparatus for manufacturing photovoltaic cells can include a conveyor, for example a roll conveyor with rollers. Other types of conveyors are possible. The conveyor transports substrate into a series of one or more deposition stations for depositing layers of material on the exposed surface of the substrate. Conveyors are described in provisional U.S. application Ser. No. 11/692,667, which is hereby incorporated by reference.

The deposition chamber can be heated to reach a processing temperature of about 380 C. to about 700 C., for example the temperature can range from about 450 C. to about 550 C., about 550 C. to about 650 C., about 570 C. to about 600 C., about 600 C. to about 640 C., or any other suitable range. The deposition chamber includes a deposition distributor connected to a deposition vapor supply. The distributor can be connected to multiple vapor supplies for deposition of various layers or the substrate can be moved through multiple and various deposition stations with its own vapor distributor and supply. The distributor can be in the form of a spray nozzle with varying nozzle geometries to facilitate uniform distribution of the vapor supply.

The window layer and the absorbing layer can include, for example, a binary semiconductor such as group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, AN, AlP, AlAs, AlSb, GaN, GaP, GaAs, GaSb, InN, InP, InAs, InSb, TlN, TlP, TlAs, TlSb, or mixtures thereof. An example of a window layer and absorbing layer is a layer of CdS coated by a layer of CdTe. A top layer can cover the semiconductor layers. The top layer can include a metal such as, for example, aluminum, molybdenum, chromium, cobalt, nickel, titanium, tungsten, or alloys thereof. The top layer can also include metal oxides or metal nitrides or alloys thereof.

As described above, a photovoltaic cell can include a transparent conductive layer on a surface of the substrate, a first semiconductor layer, the substrate supporting the semiconductor layer, and a metal layer in contact with the semiconductor layer.

The bottom layer of a photovoltaic cell can be a transparent conductive layer. A thin capping layer can be on top of and at least covering the transparent conductive layer in part. The next layer deposited is the first semiconductor layer, which can serve as a window layer and can be thinner based on the use of a transparent conductive layer and the capping layer. The next layer deposited is the second semiconductor layer, which serves as the absorber layer. Other layers, such as layers including dopants, can be deposited or otherwise placed on the substrate throughout the manufacturing process as needed.

The bottom layer can be a transparent conductive layer, and can be, for example, a transparent conductive oxide such as cadmium stannate oxide, tin oxide, or tin oxide doped with fluorine. Deposition of a semiconductor layer at high temperature directly on the transparent conductive oxide layer can result in reactions that negatively impact of the performance and stability of the photovoltaic device. Deposition of a capping layer of material with a high chemical stability (such as silicon dioxide, dialuminum trioxide, titanium dioxide, diboron trioxide and other similar entities) can significantly reduce the impact of these reactions on device performance and stability. The thickness of the capping layer should be minimized because of the high resistivity of the material used. Otherwise a resistive block counter to the desired current flow may occur. A capping layer can reduce the surface roughness of the transparent conductive oxide layer by filling in irregularities in the surface, which can aid in deposition of the window layer and can allow the window layer to have a thinner cross-section. The reduced surface roughness can help improve the uniformity of the window layer. Other advantages of including the capping layer in photovoltaic cells can include improving optical clarity, improving consistency in band gap, providing better field strength at the junction and providing better device efficiency as measured by open circuit voltage loss. Capping layers are described, for example, in U.S. Patent Publication 20050257824, which is incorporated by reference in its entirety.

The bottom layer of a photovoltaic cell can be a transparent conductive layer. A thin capping layer can be on top of and at least covering the transparent conductive layer in part. The next layer deposited is the first semiconductor layer, which can serve as a window layer and can be thinner based on the use of a transparent conductive layer and the capping layer. The next layer deposited is the second semiconductor layer, which serves as the absorber layer. Other layers, such as layers including dopants, can be deposited or otherwise placed on the substrate throughout the manufacturing process as needed.

The first semiconductor layer can serve as a window layer for the second semiconductor layer. The first semiconductor layer can be thinner than the second semiconductor layer. By being thinner, the first semiconductor layer can allow greater penetration of the shorter wavelengths of the incident light to the second semiconductor layer.

The first semiconductor layer can be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, AN, AlP, AlAs, AlSb, GaN, GaP, GaAs, GaSb, InN, InP, InAs, InSb, TlN, TlP, TlAs, TlSb, or mixtures or alloys thereof. It can be a binary semiconductor, for example it can be CdS. The second semiconductor layer can be deposited onto the first semiconductor layer. The second semiconductor can serve as an absorber layer for the incident light when the first semiconductor layer is serving as a window layer.

Similar to the first semiconductor layer, the second semiconductor layer can also be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, AN, AlP, AlAs, AlSb, GaN, GaP, GaAs, GaSb, InN, InP, InAs, InSb, TlN, TlP, TlAs, TlSb, or mixtures thereof.

The second semiconductor layer can be deposited onto a first semiconductor layer. A capping layer can serve to isolate a transparent conductive layer electrically and chemically from the first semiconductor layer preventing reactions that occur at high temperature that can negatively impact performance and stability. The transparent conductive layer can be deposited over a substrate.

Photovoltaic devices/cells fabricated using the methods discussed herein may be incorporated into one or more photovoltaic modules. The modules may by incorporated into various systems for generating electricity. For example, a photovoltaic cell may be illuminated with a beam of light to generate a photocurrent. The photocurrent may be collected and converted from direct current (DC) to alternating current (AC) and distributed to a power grid. Light of any suitable wavelength may be directed at the cell to produce the photocurrent, including, for example, more than 400 nm, or less than 700 nm (e.g., ultraviolet light). Photocurrent generated from one photovoltaic cell may be combined with photocurrent generated from other photovoltaic cells. For example, the photovoltaic cells may be part of one or more photovoltaic modules in a photovoltaic array, from which the aggregate current may be harnessed and distributed.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A method of manufacturing a photovoltaic cell comprising:
depositing a cadmium sulfide layer on a transparent conductive oxide stack;
depositing a zinc-containing layer on the cadmium sulfide layer; and
depositing a cadmium telluride layer on the zinc-containing layer.

2. The method of claim 1, further comprising forming a cadmium zinc sulfide, wherein the forming comprises annealing one or more layers.

3. The method of claim 1, wherein one or more of the depositing steps occurs at a temperature in a range of about 400 C. to about 800 C.

4. The method of claim 1, wherein one or more of the depositing steps comprises transporting a vapor.

5. The method of claim 1, further comprising annealing the cadmium sulfide layer and the zinc-containing layer.

6. The method of claim 5, further comprising annealing the cadmium telluride layer.

7. The method of claim 5, wherein the annealing comprises heating the cadmium sulfide layer and the zinc-containing layer at a temperature in a range of about 400 C. to about 800 C.

8. The method of claim 1, wherein the zinc-containing layer comprises zinc telluride or cadmium zinc telluride.

9. The method of claim 8, wherein one or more of the depositing steps controls the exchange reaction between the cadmium sulfide layer and the cadmium zinc telluride.

10. The method of claim 1, wherein the zinc-containing layer comprises zinc sulfide or a cadmium zinc telluride layer on a zinc telluride layer.

11. The method of claim 10, wherein the cadmium zinc telluride layer comprises:
a zinc concentration that is less than that of the zinc telluride layer; or a zinc content of about 2% to about 10%.

12. The method of claim 10, wherein one or more of the depositing steps controls the exchange reaction between the cadmium sulfide layer and the cadmium zinc telluride layer.

13. The method of claim 1, wherein the transparent conductive oxide stack comprises a buffer layer on a transparent conductive oxide layer, wherein the transparent conductive oxide layer is positioned on one or more barrier layers, wherein:
each of the one or more barrier layers comprises a material selected from the group consisting of silicon nitride, aluminum-doped silicon nitride, silicon oxide, aluminum-doped silicon oxide, boron-doped silicon nitride, phosphorous-doped silicon nitride, silicon oxide-nitride, and tin oxide;
the transparent conductive oxide layer comprises tin oxide, zinc oxide, or a layer of cadmium and tin; and
the buffer layer comprises a material selected from the group consisting of zinc tin oxide, tin oxide, zinc oxide, and zinc magnesium oxide.

14. The method of claim 13, further comprising annealing the transparent conductive oxide stack.

15. A photovoltaic cell comprising:
a cadmium zinc sulfide layer; and
a cadmium telluride layer on the cadmium zinc sulfide layer, wherein the cadmium zinc sulfide layer has an increased efficiency.

16. The photovoltaic cell of claim 15, wherein the crystallinity of the cadmium zinc sulfide layer is high or nearly amorphous.

17. The photovoltaic cell of claim 15, wherein the cadmium zinc sulfide layer has about 20 to about 40% zinc.

18. The photovoltaic cell of claim 15, further comprising a cadmium zinc telluride layer between the cadmium zinc sulfide layer and the cadmium telluride layer.

19. The photovoltaic cell of claim 18, wherein the cadmium zinc telluride layer has a zinc content of about 2% to about 10%.

20. A photovoltaic cell comprising:
a cadmium sulfide layer;
a zinc-containing layer on the cadmium sulfide layer; and
a cadmium telluride layer on the zinc-containing layer.
